(19) United States
(12) Patent Application Publication
(10) Pub. No.: US 2018/0358209 A1
(43) Pub. Date: Dec. 13, 2018

(54) PLASMA PROCESSING APPARATUS

(71) Applicant: Samsung Electronics Co, Ltd., Suwon-si (KR)

(72) Inventors: Jun-Soo Lee, Seoul (KR); Hak-Young Kim, Bucheon-si (KR); Chung-Won Seo, Seongnam-si (KR); Tae-Hyoung Im, Seoul (KR)

(21) Appl. No.: 15/816,882

(22) Filed: Nov. 17, 2017

(30) Foreign Application Priority Data
Jun. 8, 2017 (KR) 10-2017-0071735

(51) Int. Cl. H01J 37/32

(52) U.S. Cl. CPC H01J 37/32449; H01J 2237/334; H01J 37/321

(57) ABSTRACT

A plasma processing apparatus includes a process chamber including an inner space; an electrostatic chuck on which a substrate is loaded in the process chamber; a side-gas injection unit that is installed above the electrostatic chuck and includes at least one gas nozzle having an inclined gas flow path that is inclined with respect to a nozzle axis to obliquely supply a process gas into the process chamber from a sidewall of the process chamber; a plasma generation unit configured to generate plasma from the process gas injected into the process chamber; and a controller configured to control the electrostatic chuck, the side-gas injection unit, and the plasma generation unit. The controller controls process parameters under a cyclic ramping condition in which a cycle of the process parameters is continuously increased or decreased.

### CROSS-REFERENCE TO RELATED APPLICATION

A claim for priority under 35 U.S.C. § 119 is made to Korean Patent Application No. 10-2017-0071735, filed on Jun. 8, 2017, in the Korean Intellectual Property Office, the entire content of which is hereby incorporated by reference.

### BACKGROUND

The present inventive concepts relate to an apparatus for manufacturing a semiconductor, and more particularly, to a plasma processing apparatus.

Electronic devices such as for example semiconductor devices, LCD devices, or LED devices, may be manufactured using plasma processing apparatuses. Plasma processing apparatuses may include a plasma film deposition apparatus and a plasma etching apparatus. It may however be difficult to precisely control plasma in a process chamber of a plasma processing apparatus.

### SUMMARY

Embodiments of the inventive concepts provide a plasma processing apparatus that has increased process reliability by precisely controlling plasma.

Embodiments of the inventive concepts provide a plasma processing apparatus including a process chamber having an inner space; an electrostatic chuck configured to electrostatically hold a substrate in the process chamber; a side-gas injection unit above the electrostatic chuck and including at least one gas nozzle including an inclined gas flow path inclined with respect to a nozzle axis to obliquely supply a process gas into the process chamber from a sidewall of the process chamber, a plasma generation unit configured to generate plasma from the process gas injected into the process chamber; and a controller configured to control the electrostatic chuck, the side-gas injection unit, and the plasma generation unit.

Embodiments of the inventive concepts provide a plasma processing apparatus including a process chamber having an inner space; an electrostatic chuck configured to electrostatically hold a substrate in the process chamber; a side-gas injection unit that is installed above the electrostatic chuck and injects a process gas into the process chamber from a sidewall of the process chamber; an upper-gas injection unit configured to inject the process gas in a direction toward the substrate from above the process chamber; a plasma generation unit configured to generate plasma from the process gas injected into the process chamber; and a controller configured to control at least one process parameter of pressure of the process chamber, temperature of the electrostatic chuck, flow rate of the process gas injected from the side-gas injection unit and the upper-gas injection unit and power of the plasma generation unit as a cyclic ramping condition.

Embodiments of the inventive concepts provide a plasma processing apparatus including a process chamber having an inner space; an electrostatic chuck configured to electrostatically hold a substrate in the process chamber; a side-gas injection unit above the electrostatic chuck and configured to obliquely inject a process gas into the process chamber from a sidewall of the process chamber through at least one gas nozzle including an inclined gas flow path that is inclined with respect to a nozzle axis; an upper-gas injection unit configured to inject the process gas in a direction toward the substrate from above the process chamber; a plasma generation unit configured to generate plasma from the process gas injected into the process chamber; and a controller configured to control at least one process parameter of pressure of the process chamber, temperature of the electrostatic chuck, flow rate of the process gas injected from the side-gas injection unit and the upper-gas injection unit and power of the plasma generation unit as a cyclic ramping condition.

The plasma processing apparatus according to the inventive concepts includes the side-gas injection unit that is configured to obliquely inject the process gas into the process chamber from a sidewall of the process chamber, and thus plasma in the process chamber may be precisely controlled.

The plasma processing apparatus according to the inventive concepts includes a controller configured to control a process parameter as a cyclic ramping condition, and thus plasma in the process chamber may be precisely controlled.

### BRIEF DESCRIPTION OF THE DRAWINGS

Embodiments of the inventive concepts will be more clearly understood from the following detailed description taken in conjunction with the accompanying drawings in which:

FIG. 1 illustrates a cross-sectional view of a plasma processing apparatus according to an embodiment of the inventive concepts;

FIGS. 2A and 2B respectively illustrate a perspective view and a plan view of a side-gas injection unit in the plasma processing apparatus of FIG. 1;

FIG. 3 illustrates a magnified cross-sectional view of a gas nozzle included in the side-gas injection unit of FIGS. 2A and 2B;

FIG. 4 illustrates a partial cross-sectional view explanatory of a branch gas flow path formed in a gas distribution plate of the side-gas injection unit of FIGS. 2A and 2B;

FIG. 5 illustrates a diagram explanatory of a buffer gas flow path formed in the branch gas flow path of FIG. 4;

FIG. 6 illustrates a diagram according to a comparative example for comparison with the diagram of FIG. 5;

FIGS. 7 and 8 illustrate cross-sectional views explanatory of plasma states of plasma in a processing apparatus according to an embodiment of the inventive concepts;

FIGS. 9, 10 and 11 illustrate graphs explanatory of an etch-rate and uniformity of selectivity of a material film formed using a plasma processing apparatus according to an embodiment of the inventive concepts;

FIGS. 12, 13 and 14 illustrate diagrams explanatory of a process parameter control method by a control unit of the plasma processing apparatus of FIG. 1, according to an embodiment of the inventive concepts;

FIGS. 15, 16 and 17 illustrate diagrams explanatory of a method of controlling a process parameter by a controller of the plasma processing apparatus of FIG. 1, according to an embodiment of the inventive concepts;

FIGS. 18, 19 and 20 illustrate diagrams explanatory of a process parameter control method by a controller of the plasma processing apparatus of FIG. 1, according to an embodiment of the inventive concepts;

FIG. 21 illustrates a diagram explanatory of a process parameter control method by a controller of the plasma processing apparatus of FIG. 1, according to an embodiment of the inventive concepts; and

FIG. 22 illustrates a flowchart of a method of processing plasma via the plasma processing apparatus of FIG. 1, according to an embodiment of the inventive concepts.

### DETAILED DESCRIPTION OF THE EMBODIMENTS

Hereafter, the inventive concept will be described more fully with reference to the accompanying drawings. The embodiments of the inventive concept may be realized by a single embodiment, and also, may be realized by a combination of more than one embodiment. Therefore, the technical scope of the inventive concept should not be construed by one of the embodiment.

As is traditional in the field of the inventive concepts, embodiments may be described and illustrated in terms of blocks which carry out a described function or functions. These blocks, which may be referred to herein as units or modules or the like, are physically implemented by analog and/or digital circuits such as logic gates, integrated circuits, microprocessors, microcontrollers, memory circuits, passive electronic components, active electronic components, optical components, hardwired circuits and the like, and may optionally be driven by firmware and/or software. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the inventive concepts. Likewise, the blocks of the embodiments may be physically combined into more complex blocks without departing from the scope of the inventive concepts.

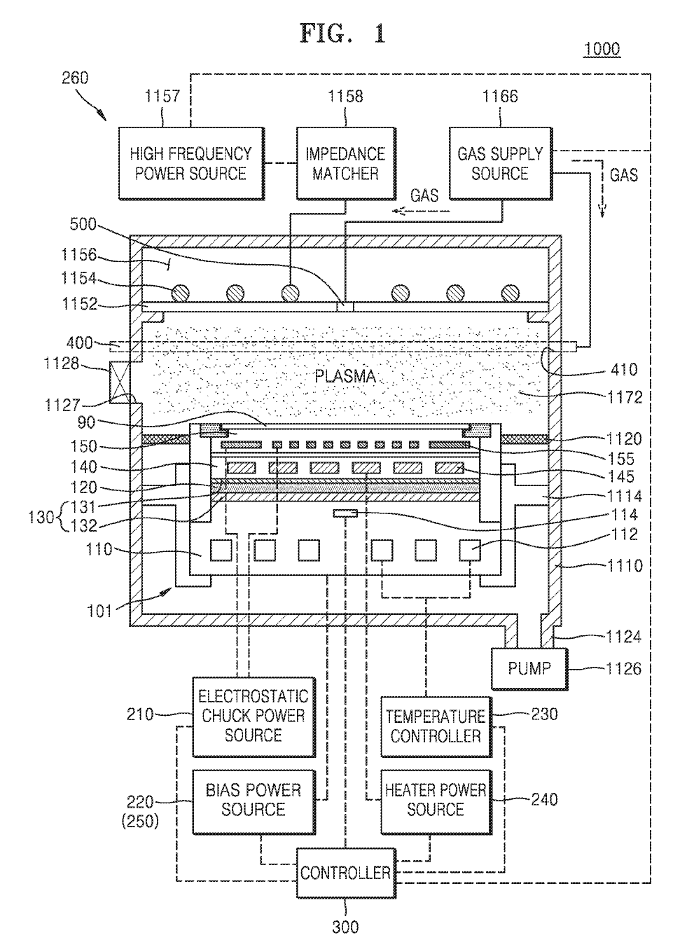

FIG. 1 illustrates a cross-sectional view of a plasma processing apparatus 1000 according to an embodiment of the inventive concepts.

According to an embodiment of the inventive concepts, the plasma processing apparatus 1000 may be an inductively coupled plasma (ICP) etching apparatus. However, other embodiments of the inventive concepts are not limited to an ICP etching apparatus, and may be applied to any apparatus that uses plasma. For example, according to other embodiments of the inventive concepts, the plasma processing apparatus 1000 may be a charge coupled plasma (CCP) etching apparatus or a plasma deposition apparatus. Also, the technical scope of the inventive concepts is not limited to the plasma processing apparatus 1000 of FIG. 1.

As described, the plasma processing apparatus 1000 in FIG. 1 is an inductively coupled plasma processing apparatus. The plasma processing apparatus 1000 processes a substrate 90. That is, plasma processing apparatus 1000 plasma etches substrate 90 placed in a process chamber 1110 by using ICP generated by an inductively coupled method. The substrate 90 may be a wafer, such as for example a silicon wafer. The process chamber 1110 may be a process chamber including an inner space, such as for example a plasma chamber. A material film, such as for example an oxide film or a nitride film, may be formed on the substrate 90.

The plasma processing apparatus 1000 includes an electrostatic chuck 101 on which the substrate 90 is mounted in the process chamber 1110, a side-gas injection unit 400 and an upper-gas injection unit 500 that inject a process gas into the process chamber 1110, and plasma generation units 250 and 260 that generate plasma from the process gas injected into the process chamber 1110. The plasma processing apparatus 1000 may include a controller 300 to control the electrostatic chuck 101, the side-gas injection unit 400, the upper-gas injection unit 500, and the plasma generation units 250 and 260. In some embodiments of the inventive concepts, the plasma processing apparatus 1000 may not include the upper-gas injection unit 500 if it is unnecessary.

Configurations of each of the parts of the plasma processing apparatus 1000 will now be described. The electrostatic chuck 101 includes a base 110 and a heater dielectric layer 140 and an electrostatic dielectric layer 150 that are attached to the base 110 by an adhesion layer 130. The adhesion layer 130 may for example have a double layer structure including a first adhesive 131 and a second adhesive 132. A metal plate 120 may further be provided between the first and second adhesives 131 and 132. The base 110 may have a circular shape or a disc shape. The base 110 may include a metal, such as for example aluminum, titanium, stainless steel, tungsten, or an alloy of these metals.

When the inner space of the process chamber 1110 in which the electrostatic chuck 101 is installed is exposed to a high temperature atmosphere and the substrate 90 is exposed to high temperature plasma, damage such as for example ion bombardment may be caused to the substrate 90. In order to avoid damage to the substrate 90 and for uniform plasma processing, cooling of the substrate 90 may be needed.

In order to cool the substrate 90, a coolant channel 112 through which a coolant flows may be provided in the base 110. The coolant may include for example water, ethylene glycol, silicon oil, liquid Teflon, or a mixture of glycol and water. The coolant channel 112 may have a concentric or helical pipe structure with respect to a center axis of the base 110. The coolant channel 112 may be connected to a temperature adjuster (controller) 230, and the controller 300 (connection not shown). Flow speed and temperature of the coolant that circulates in the coolant channel 112 may be controlled by the temperature adjuster 230 and the controller 300.

The base 110 is electrically connected to a bias power source 220. A high frequency or radio frequency power is applied to the base 110 from the bias power source 220, and accordingly, the base 110 may perform as an electrode for generating plasma. The bias power source 220 may be included in the plasma generation unit 250.

The base 110 includes a temperature sensor 114. The temperature sensor 114 may transmit a temperature of the base 110 to the controller 300. Temperatures of the electrostatic chuck 101 and the substrate 90 may be estimated based on the temperatures measured by the temperature sensor 114.

The heater dielectric layer 140 may include an embedded heater electrode 145. The heater dielectric layer 140 may include a dielectric such as a ceramic which may be for example an aluminum oxide (Al₂O₃), an aluminum nitride (AlN) layer, a yttrium oxide (Y₂O₃) layer, or a resin such as polyimide for example. The heater dielectric layer 140 may have a circular shape or a disc shape.

The heater electrode 145 may include a conductive metal, such as for example tungsten (W), copper (Cu), nickel (Ni), molybdenum (Mo), titanium (Ti), a Ni—Cr alloy, and a Ni—Al alloy, or a conductive ceramic such as for example tungsten carbide (WC), molybdenum carbide (MoC), and titanium nitride (TiN).

The (embedded) heater electrode 145 is electrically connected to a heater power source 240, and the controller 300 (connection not shown). The heater electrode 145 may be heated by power such as for example an alternating current voltage from the heater power source 240, and thus the temperatures of the electrostatic chuck 101 and the substrate 90 may be controlled. The heater electrode 145 may have a concentric or helical pattern with respect to a center axis of the heater dielectric layer 140.

The electrostatic dielectric layer 150 may include an embedded clamp electrode 155. The clamp electrode 155 may be referred to as an adsorption electrode. The electrostatic dielectric layer 150 may include a dielectric such as a ceramic which may be for example an aluminum oxide (Al₂O₃), an aluminum nitride (AlN) layer, a yttrium oxide (Y₂O₃) layer, or a resin such as a polymide for example. The electrostatic dielectric layer 150 may have a circular shape or a disc shape.

The substrate 90 may be disposed on the electrostatic dielectric layer 150. The clamp electrode 155 may include a conductive metal such as for example tungsten (W), copper (Cu), nickel (Ni), molybdenum (Mo), titanium (Ti), a Ni—Cr alloy, and a Ni—Al alloy, or a conductive ceramic such as for example tungsten carbide (WC), molybdenum carbide (MoC), and titanium nitride (TiN).

The clamp electrode 155 is electrically connected to an electrostatic chuck (ESC) power source 210, and a controller 300 (connection not shown). An electrostatic force is generated between the clamp electrode 155 and the substrate 90 by power such as for example a direct current voltage applied from the ESC power source 210, and thus the substrate 90 may be electrostatically held to the electrostatic dielectric layer 150.

The ESC power source 210, the bias power source 220, the heater power source 240, and the temperature adjuster 230 may be controlled by the controller 300. For example, the controller 300 may read temperatures of the electrostatic chuck 101 and the substrate 90 based on the temperatures measured from the temperature sensor 114, and an amount of heat generated from the heater electrode 145 may be controlled by controlling power of the heater power source 240. Accordingly, the temperatures of the electrostatic chuck 101 and the substrate 90 may be appropriately controlled.

The electrostatic chuck 101 is supported by a supporting unit 1114 fixed on an inner wall of the process chamber 1110. A baffle plate 1120 is provided between the electrostatic chuck 101 and the inner wall of the process chamber 1110. An exhaust tube 1124 is provided at a lower part of the process chamber 1110, and the exhaust tube 1124 is connected to a vacuum pump 1126. A gate valve 1128 is provided on an outer wall of the process chamber 1110 to open and close an opening 1127 through which the substrate 90 may be placed into and taken out from the process chamber 1110.

A dielectric window 1152 separated from the electrostatic chuck 101 is provided on a ceiling of the process chamber 1110. An antenna room 1156 that accommodates a high frequency antenna 1154 having a spiral or concentric coil shape is integrally disposed as part of the process chamber 1110. The high frequency antenna 1154 is electrically connected to a high frequency (RF) power source 1157 through an impedance matcher 1158. The RF power source 1157 may output an RF power appropriate for generating plasma. The impedance matcher 1158 may be provided for matching an impedance of the RF power source 1157 with the high frequency antenna 1154. The RF power source 1157, the impedance matcher 1158, and the high frequency antenna 1154 may constitute the plasma generation unit 260.

A gas supply source 1166 injects a process gas into the process chamber 1110 through the upper-gas injection unit 500 or the side-gas injection unit 400. The gas from the gas supply source 1166 may be injected into the process chamber 1110 via the upper-gas injection unit 500 from above the process chamber 1110 for example through a hole formed in the dielectric window 1152. The process gas may be an etchant gas. The gas supply source 1166 may be formed above an upper side of the electrostatic chuck 101 and may also inject a process gas through the side-gas injection unit 400 that includes a gas nozzle 410. The gas supply source 1166 may supply a process gas into the process chamber 1110 through the gas nozzle 410 installed on a sidewall of the process chamber 1110.

A process gas injected into the process chamber 1110 through the side-gas injection unit 400 may differ from the process gas supplied through the upper-gas injection unit 500. For example, the side-gas injection unit 400 may supply an etchant gas and the upper-gas injection unit 500 may supply a protection gas that protects an etch pattern to be etched.

In order to perform an etching process by using the plasma processing apparatus 1000, the substrate 90 may be loaded (mounted) on the electrostatic chuck 101 in the process chamber 1110 by opening a gate valve 1128. The substrate 90 may be held to the electrostatic chuck 101 by an electrostatic force generated from the electrostatic chuck 101 by applying power to the electrostatic chuck 101 from the ESC power source 210.

A process gas, such as for example an etchant gas, may be injected into the process chamber 1110 from the gas supply source 1166 through the upper-gas injection unit 500 and the side-gas injection unit 400. At this point, pressure in the process chamber 1110 may be maintained at a certain level by the vacuum pump 1126, under control of the controller 300. Power may be applied to the high frequency antenna 1154 from the high frequency power source 1157 through the impedance matcher 1158. Also, power may be applied to the base 110 from the bias power source 220.

An etchant gas injected into the process chamber 1110 may be uniformly distributed in a processing room 1172 of the process chamber 1110 below the dielectric window 1152. A magnetic field may be generated around the high frequency antenna 1154 by a current that flows in the high frequency antenna 1154, and magnetic lines may pass into the processing room 1172 through the dielectric window 1152. An induced electric field is generated by a time variance of the magnetic field, and electrons accelerated by the induced electric field may collide with molecules or atoms of the etchant gas, and thus, plasma may be generated.

As described above, plasma is supplied to the substrate 90 by using the high frequency power source 1157, the impedance matcher 1158, the high frequency antenna 1154, and the bias power source 220, and thus a substrate processing, that is an etching process, may be performed in the processing room 1172. In order to precisely control the plasma generated in the processing room 1172 of the process chamber 1110, the plasma processing apparatus 1000 according to the inventive concepts includes the side-gas injection unit 400 in addition to the upper-gas injection unit 500. Also, the plasma processing apparatus 1000 includes the controller 300 to precisely control plasma. The configurations and operations of the side-gas injection unit 400 and the controller 300 will be described below.

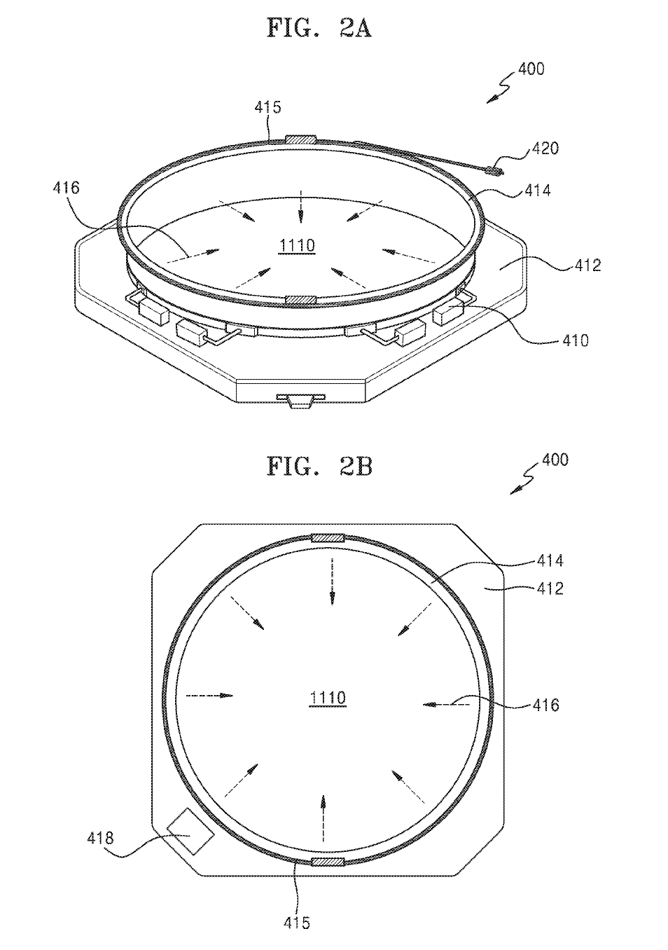

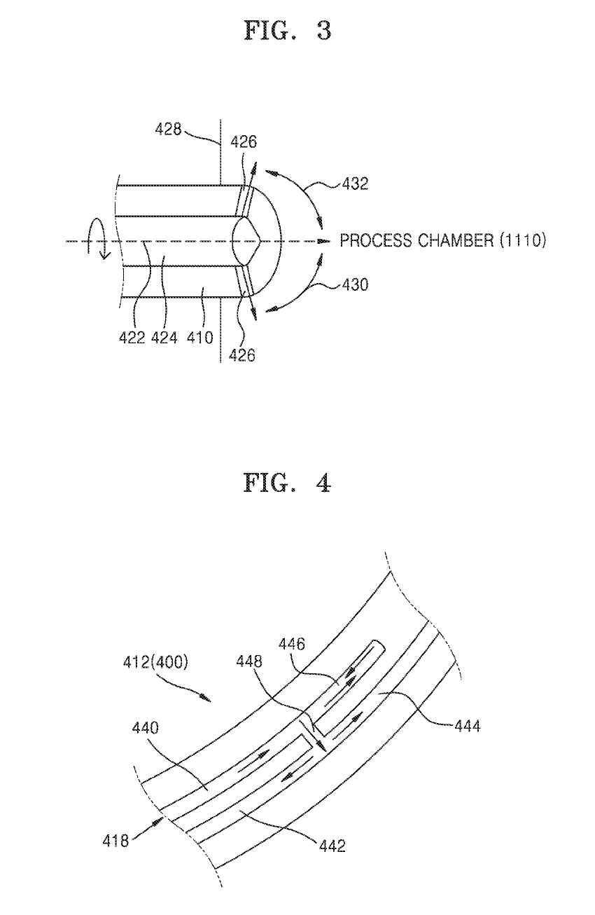

FIGS. 2A and 2B respectively illustrate a perspective view and a plan view of the side-gas injection unit 400 in the plasma processing apparatus 1000 of FIG. 1. FIG. 3 illustrates a magnified cross-sectional view of the gas nozzle 410 included in the side-gas injection unit 400 of FIGS. 2A and 2B.

In detail, in FIGS. 2A, 2B, and 3, like reference numerals are used to indicate elements identical to the elements of FIG. 1. The side-gas injection unit 400 includes a gas distribution plate 412, a plurality of gas nozzles 410, and a cylindrical member 414. The gas distribution plate 412 includes a gas inlet 418. The gas inlet 418 is connected to the gas inlet line 420 (connection not shown), and a process gas is provided from the gas inlet line 420 to the gas inlet 418, and from the gas inlet 418 the process gas enters into the gas distribution plate 412. A process gas supplied to the gas distribution plate 412 is injected into an inner side (i.e., the processing room 1172 as shown in FIG. 1) of the process chamber 1110 through the nozzles 410 and is provided along gas flow paths 416 from the gas nozzles 410.

The gas nozzles 410 are installed between the gas distribution plate 412 and the cylindrical member 414. The cylindrical member 414 may be coupled to the process chamber 1110 having a cylindrical shape. A sealing member 415 is disposed on the cylindrical member 414, and the sealing member 415 tightly couples to the process chamber 1110. The plurality of gas nozzles 410 may be disposed as spaced apart or separated from each other along a circumferential direction of the cylindrical member 414 of the cylindrically-shaped process chamber 1110. In the embodiment as shown in FIGS. 2A and 2B, eight gas nozzles 410 are included. A process gas injected from the gas nozzles 410 may be uniformly injected towards the inner side of the process chamber 1110. In other embodiments of the inventive concepts, the side-gas injection unit 400 may include more or less than eight gas nozzles 410.

As depicted in FIG. 3, each of the gas nozzles 410 includes a horizontal gas path 424 that is horizontal with respect to a nozzle axis 422 and inclined gas paths 426 that are inclined with respect to the nozzle axis 422. The inclined gas paths 426 are respectively inclined by a first inclination angle 430 in a clockwise direction with respect to the nozzle axis 422 and a second inclination angle 432 in a counter clockwise direction with respect to the nozzle axis 422. In the embodiment of FIG. 3, two inclined gas paths 426 are depicted above and below with respect to the nozzle axis 422. However, in other embodiments of the inventive concepts, only one inclined gas path 426 may be included in the gas nozzle. The horizontal gas path 424 and the inclined gas paths 426 are connected to each other. The nozzle axis 422 may be a perpendicular direction with respect to a sidewall 428 of the process chamber 1110. The gas nozzle 410 obliquely injects a process gas into the process chamber 1110 from the sidewall 428 of the process chamber 1110 through the inclined gas paths 426.

The gas nozzles 410 may be rotatable gas nozzles that rotate with respect to the nozzle axis 422. If only one inclined gas path 426 is formed with respect to the nozzle axis 422, since the one inclined gas path 426 is able to rotate with respect to the nozzle axis 422, the gas nozzles 410 may obliquely inject a process gas into the process chamber 1110 with the first inclination angle 430 in a clockwise direction with respect to the nozzle axis 422 and the second inclination angle 432 in a counter-clockwise direction with respect to the nozzle axis 422. The first inclination angle 430 and the second inclination angle 432 may be the same. Also, the first inclination angle 430 and the second inclination angle 432 may be in a range from about 10 degrees to about 80 degrees from the nozzle axis 422.

When a process gas is obliquely injected into the process chamber 1110, a residence time of the process gas above the substrate 90 in the process chamber 1110 may be controlled, and thus, plasma may be precisely controlled.

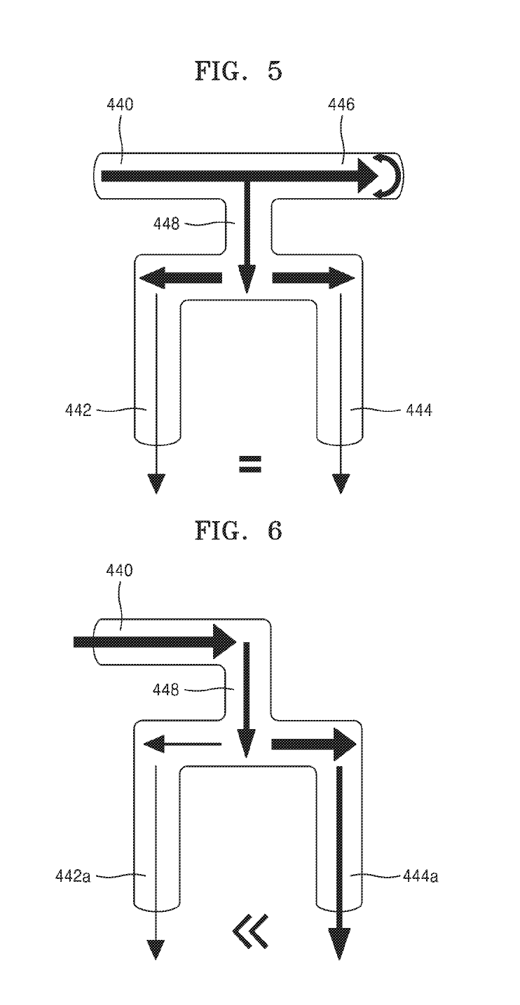

FIG. 4 illustrates a partial cross-sectional view explanatory of branch gas flow paths 440, 442, and 444 included in the gas distribution plate 412 of the side-gas injection unit 400 of FIGS. 2A and 2B.

In detail, in FIG. 4, parts of the branch gas flow paths 440, 442, and 444 included in the gas distribution plate 412 of the side-gas injection unit 400 are depicted. As depicted in FIG. 4, the gas distribution plate 412 of the side-gas injection unit 400 includes a plurality of the branch gas flow paths 440, 442, and 444 connected to the gas inlet 418 through which a process gas enters the gas distribution plate 412.

A process gas entered into a single branch gas flow path 440 from the gas inlet 418 as indicated by an arrow is divided into two branch paths, that is, the first branch gas flow path 442 and the second branch gas flow path 444 at a branch point 448. The first and second branch gas flow paths 442 and 444 may be further divided to provide eight branch gas flow paths in the same method as depicted in FIG. 4, and the eight branch gas flow paths may be respectively connected to eight inclined gas paths such as inclined gas paths 426 of gas nozzles 410 as shown in FIG. 3.

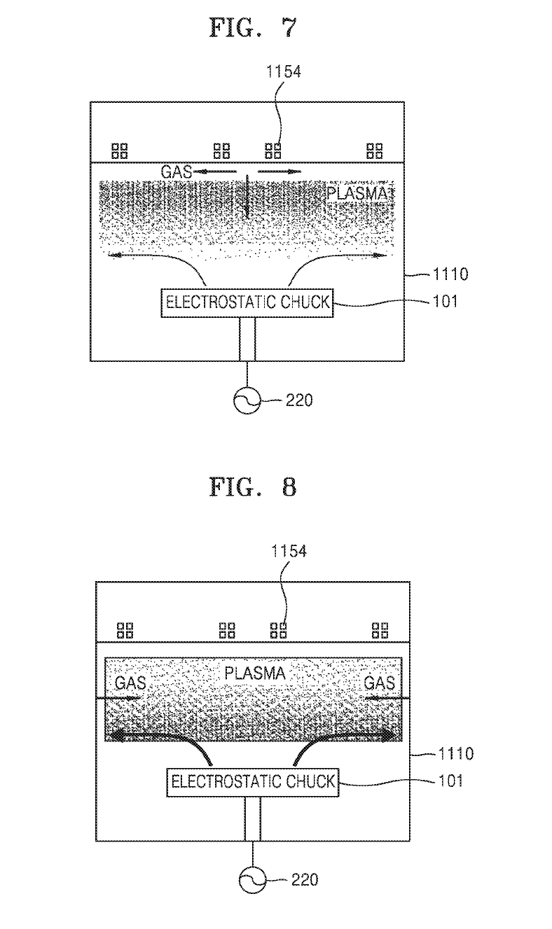

When a process gas entered from a single branch gas flow path 440 is divided into the first and second branch gas flow paths 442 and 444 at the branch point 448, a part of the process gas passes through a buffer gas flow path 446. In this manner, when a process gas passes through the buffer gas flow path 446, the process gas is uniformly discharged from the first and second branch gas flow paths 442 and 444, which will be described in detail with reference to FIG. 5.

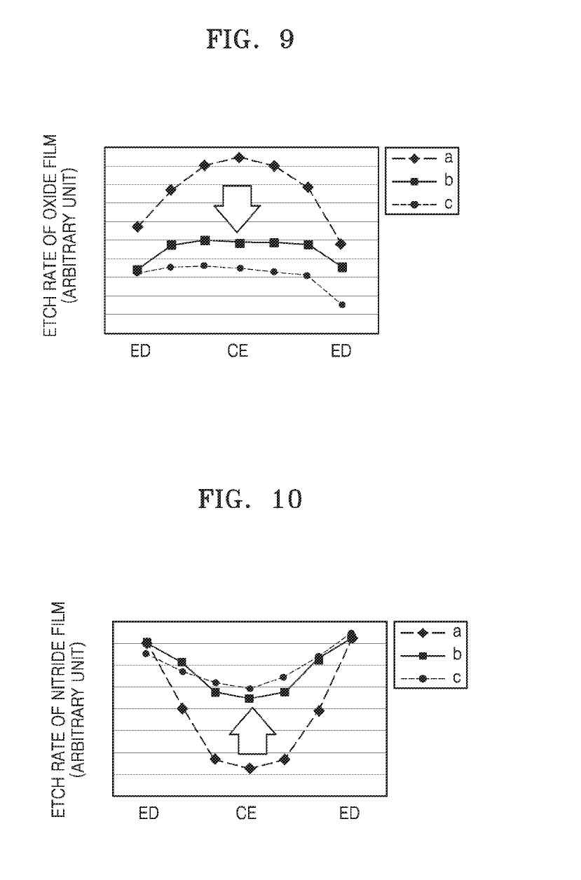

FIG. 5 illustrates a diagram explanatory of the buffer gas flow path 446 in the branch gas flow paths 440, 442, and 444 of FIG. 4. FIG. 6 illustrates a diagram according to a comparative example for comparison with the diagram of FIG. 5.

In detail, as in the embodiment of the inventive concepts described with respect to FIG. 4, FIG. 5 shows a case in which the buffer gas flow path 446 is included along with the branch gas flow paths 440, 442, and 444. FIG. 6 shows a case in which the buffer gas flow path 446 is not included along with the branch gas flow paths 440, 442, and 444, in contrast to FIG. 5.

As depicted in FIG. 5, a process gas entered through a single branch gas flow path 440 is branched to the first and second branch gas flow paths 442 and 444 at the branch point 448 through the buffer gas flow path 446. That is, since part of the process gas entered through the single gas flow path 440 passes through the buffer gas flow path 446 before passing to the branch point 448, the process gas is evenly distributed to the first and second branch gas flow paths 442 and 444 at the branch point 448. Accordingly, the process gas may be equally discharged through the first and second branch gas flow paths 442 and 444.

However, as depicted in FIG. 6, a process gas entered through the single branch gas flow path 440 is branched to first and second branch gas flow paths 442a and 444a at the branch point 448 without passing through a buffer gas flow path such as buffer gas flow path 446 shown in FIG. 5. Since the process gas in FIG. 6 does not pass through a buffer gas flow path such as buffer gas flow path 446 shown in FIG. 5, a larger amount of the process gas may flow in the second branch gas flow path 444a than in the first branch gas flow path 442a. Accordingly, in the comparative example of FIG. 6, the process gas may be unequally discharged through the first and second branch gas flow paths 442a and 444a.

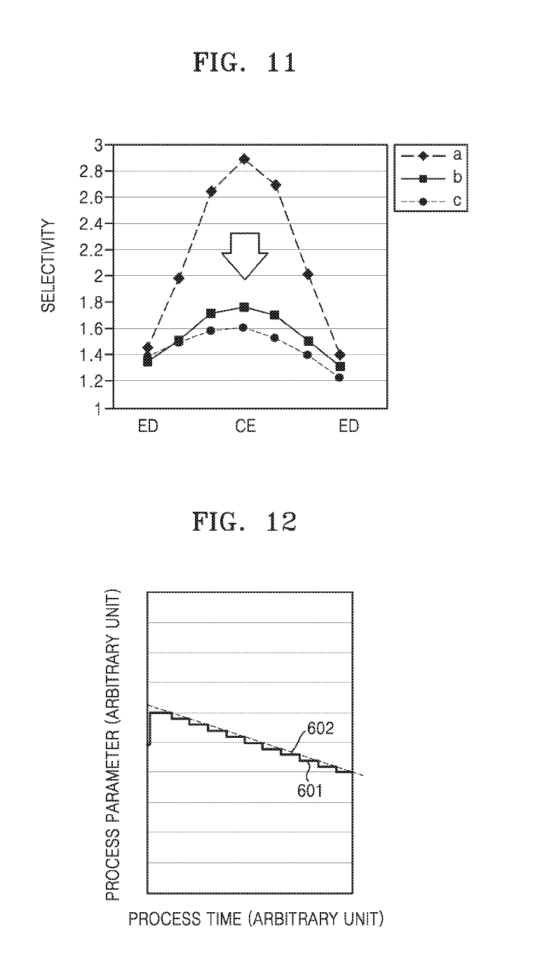

FIGS. 7 and 8 illustrate cross-sectional views explanatory of plasma in the plasma processing apparatus 1000 according to an embodiment of the inventive concept.

In detail, in FIGS. 7 and 8, like reference numerals are used to indicate elements that are identical to the elements of FIG. 1. Also, in FIGS. 7 and 8, for convenience of explanation, descriptions that are identical to that of FIG. 1 will be omitted. FIG. 7 shows a plasma state generated in the process chamber 1110 by a process gas injected through the upper-gas injection unit 500 (refer to FIG. 1). FIG. 8 shows a plasma state generated in the process chamber 1110 by a process gas injected through the side-gas injection unit 400 (refer to FIG. 1).

As depicted in FIG. 7, when a process gas is injected from an upper side of the process chamber 1110, a small amount of plasma is generated near the electrostatic chuck 101 and in sidewall directions of the process chamber 1110. As depicted in FIG. 8, when a process gas is injected through sides of the process chamber 1110, a large amount of plasma is generated near the electrostatic chuck 101 and in the sidewall directions of the process chamber 1110. As described above, when a process gas is injected into the process chamber 1110 through an upper side, a sidewall, or upper side and sidewall, the density of plasma may be uniformly controlled.

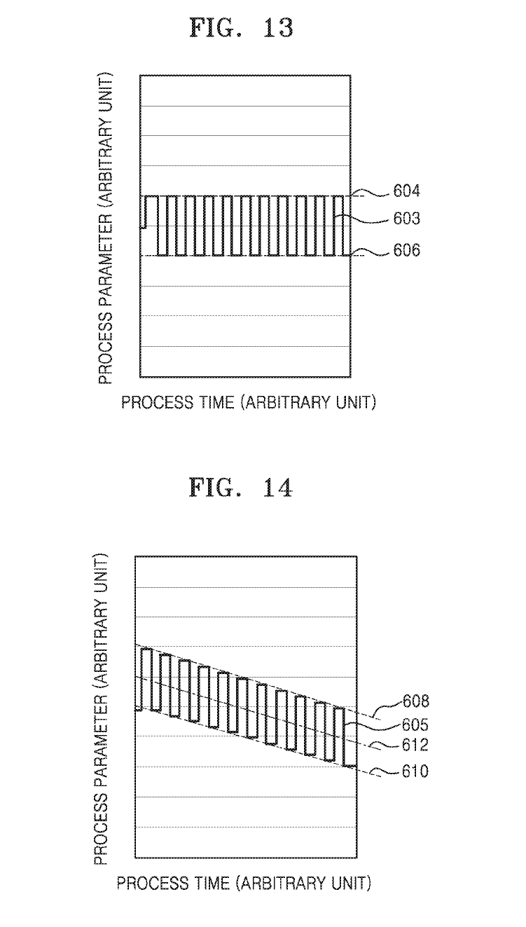

FIGS. 9, 10 and 11 illustrate graphs explanatory of an etch-rate and the uniformity of selectivity of a material film formed using the plasma processing apparatus 1000 according to an embodiment of the inventive concept.

In detail, FIGS. 9 and 10 respectively show etch rates of an oxide film and a nitride film formed on the substrate 90 (refer to FIG. 1), and FIG. 11 shows the uniformity of selectivity of the material film with respect to a mask film using the plasma processing apparatus 100 of FIGS. 1 through 4. In FIGS. 9 through 11, the horizontal axes indicate location on the substrate 90, wherein CE indicates a central region of the substrate 90 (refer to FIG. 1), and ED indicates corner (edge) regions of the substrate 90. In FIGS. 9 and 10 the vertical axes represent etch rate using arbitrary units for the purpose of comparison. In FIG. 11 the vertical axis indicates a ratio of selectivity between the material film and the mask film.

In FIGS. 9 through 11, reference character “a” indicates a case in which a process gas is injected into the process chamber 1110 by the upper-gas injection unit 500 (refer to FIG. 1) of the plasma processing apparatus 1000 of FIGS. 1 through 4. Reference character “b” indicates a case in which a process gas is injected by the side-gas injection unit 400 (refer to FIG. 1) at the second inclination angle 432 (e.g., raised by 75 degrees with respect to the nozzle axis 422 shown in FIG. 3). Reference character “c” indicates a case in which a process gas is injected by the side-gas injection unit 400 (refer to FIG. 1) at the first inclination angle 430 (e.g., lowered by 75 degrees with respect to the nozzle axis 422 shown in FIG. 3).

As depicted in FIGS. 9 and 10, an etch rate difference between the central region CE and the corner (edge) regions ED of the substrate 90 is reduced in the case when the process gas is injected with either of the first and second inclination angles 430 and 432 (refer to FIG. 3) by the side-gas injection unit 400 (refer to FIG. 1) when compared to the case when the process gas is injected by the upper-gas injection unit 500 (refer to FIG. 1).

Also, as depicted in FIG. 11, a difference of the selectivity between the material film and the mask film at the central region CE and at the corner (edge) regions ED of the substrate 90 is smaller in the case when a process gas is injected with either of the first and second inclination angles 430 and 432 by the side-gas injection unit 400 (refer to FIG. 1) than the case when the process gas is injected by the upper-gas injection unit 500 (refer to FIG. 1). That is, the uniformity of selectivity may be improved using the side-gas injection unit 400.

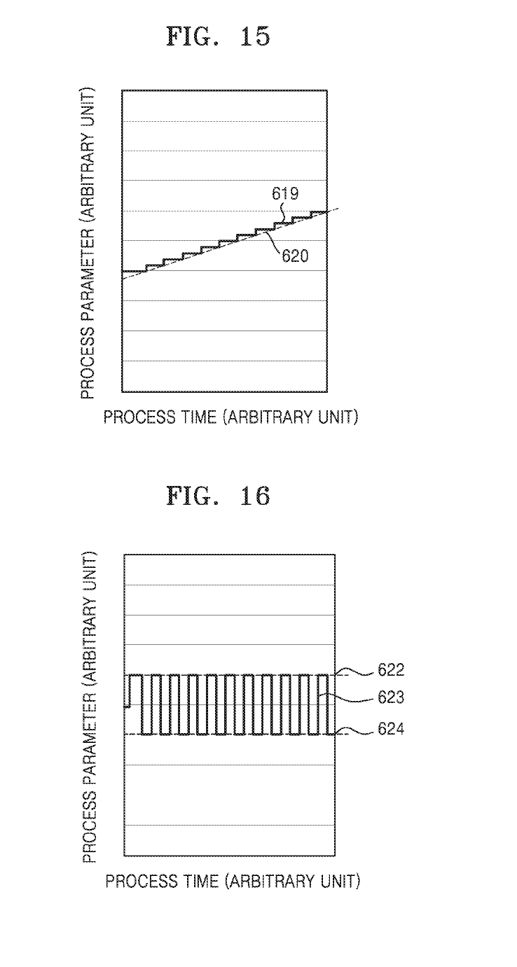

FIGS. 12, 13 and 14 illustrate diagrams explanatory of a process parameter control method by the controller 300 of the plasma processing apparatus 1000 of FIG. 1, according to an embodiment of the inventive concepts. In FIGS. 12-14, the horizontal axes indicate the process time of a process parameter in arbitrary units of time for the purpose of comparison, and the vertical axes represent change of the process parameter in arbitrary units for the purpose of comparison.

In detail, as depicted in FIG. 14, the controller 300 of the plasma processing apparatus 1000 (refer to FIG. 1) may control at least one of process parameters as a cyclic ramping condition 605. The process parameter may include for example pressure of the process chamber 1110, temperature of the electrostatic chuck 101, gas flow of the rate side-gas injection unit 400 and/or the upper-gas injection unit 500, and power of the plasma generation units 250 and 260.

The cyclic ramping condition 605 may denote a combination of a ramping condition 601 in which a process parameter is continuously decreased along with a process time as depicted in FIG. 12, and a cyclic condition 603 in which a process parameter is cyclically changed along with a process time as depicted in FIG. 13. The cyclic ramping condition 605 will be described in detail with reference to FIGS. 12 through 14 by using a process gas as a process parameter injected into the process chamber 1110.

As depicted in FIG. 12, the ramping condition 601 may denote the injection of a process parameter (e.g., a process gas) into a process chamber is continuously decreased along with a process time. That is, FIG. 12 may for example show change of a process gas injection flow rate into the process chamber 1110 as process time lapses. FIG. 12 shows a case that a maximum value 602 of a process parameter as the ramping condition 601 is continuously decreased.

As depicted in FIG. 13, the cyclic condition 603 may denote the cyclical change of a process parameter. That is, FIG. 13 may for example show change of a process gas injection flow rate into the process chamber 1110 as process time lapses. FIG. 13 shows a case that a maximum value 604 and a minimum value 606 of a cycle of a process parameter as the cyclic condition 603 are sequentially changed. The cyclic condition may be referred to as a pulse condition or a modulation condition.

As depicted in FIG. 14, the cyclic ramping condition 605 may be characterized as a continuous decrease of the process parameter together with cyclical change of the process parameter. That is, FIG. 14 may for example show change of a process gas injection flow rate into the process chamber 1110 as process time lapses. The cyclic ramping condition 605 may denote a case that a maximum value 608 and a minimum value 610 of a cycle of a process parameter are continuously decreased. The cyclic ramping condition 605 may denote a case that an intermediate value 612 of a cycle of a process parameter is continuously decreased.

When the plasma processing apparatus 1000 controls a process parameter (e.g., a process gas injected into the process chamber 1110) as a cyclic ramping condition 605 as described with respect to FIG. 14, the process gas may be uniformly distributed in the process chamber 1110 and un-reacted or by-product gases generated as a result of processing may be smoothly discharged to the outside of the process chamber 1110, and thus plasma may be precisely controlled. Accordingly, the plasma processing apparatus 1000 may increase uniformity of etch rate and/or uniformity of selectivity of a material film with respect to a mask in a plasma processing process (e.g., an etching process of a substrate).

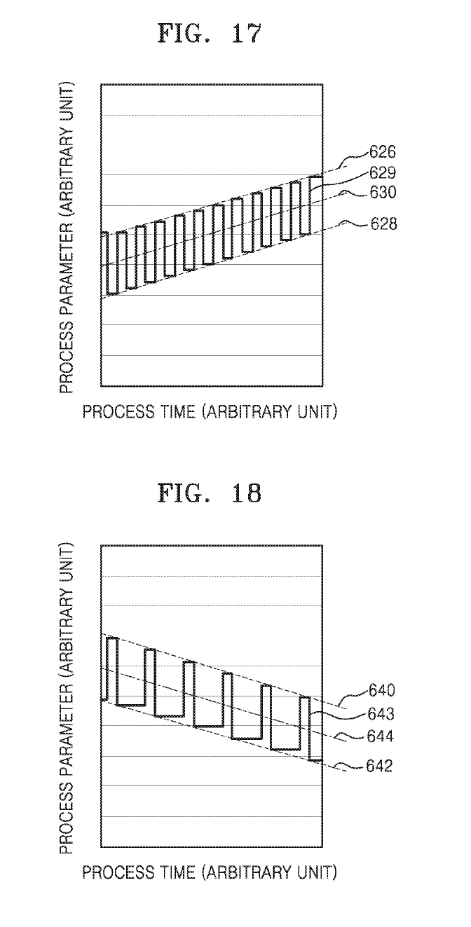

FIGS. 15, 16 and 17 illustrate diagrams explanatory of a method of controlling a process parameter by the controller 300 of the plasma processing apparatus 1000 of FIG. 1, according to an embodiment of the inventive concepts.

In detail, when the control method of FIGS. 15 through 17 is compared with that of FIGS. 12 through 14, the control method described with reference to FIGS. 15 through 17 may be the same as the control method described with reference to FIGS. 12 through 14 except that a process parameter is controlled as a cyclic ramping condition 629 by including a ramping condition 619 in which the process parameter continuously increases along with a process time. In describing FIGS. 15 through 17, contents that are identical to that of FIGS. 12 through 14 may be briefly described or omitted.

As depicted in FIG. 17, the controller 300 of the plasma processing apparatus 1000 (refer to FIG. 1) may control at least one of the above noted process parameters described with respect to FIGS. 12-14 as the cyclic ramping condition 629. The cyclic ramping condition 629 may denote a combination of a ramping condition 619 in which a process parameter is continuously increased along with a process time, and a cyclic condition 623 in which the process parameter is cyclically changed along with the process time.

As depicted in FIG. 15, the ramping condition 619 may denote the injection of a process parameter (e.g., a process gas) into a process chamber is continuously increased along with a process time. That is, FIG. 15 may for example show change of a process gas injection flow rate into the process chamber 1110 as process time lapses. FIG. 15 shows a case that a minimum value 620 of a process parameter as the ramping condition 619 is continuously increased.

As depicted in FIG. 16, the cyclic condition 623 may denote a cyclical change of a process parameter. That is, FIG. 16 may for example show change of a process gas injection flow rate into the process chamber 1110 as process time lapses. FIG. 16 shows the sequential change of a maximum value 622 and a minimum value 624 of a cycle of a process parameter as the cyclic condition 623.

As depicted in FIG. 17, the cyclic ramping condition 629 may be characterized as a continuous increase of a process parameter together with a cyclical change of the process parameter. That is, FIG. 17 may for example show change of a process gas injection flow rate into the process chamber 1110 as process time lapses. The cyclic ramping condition 629 may denote a case that a maximum value 626 and a minimum value 628 of a cycle of a process parameter are continuously increased. The cyclic ramping condition 629 may denote a case that an intermediate value 630 of a cycle of a process parameter is continuous increased.

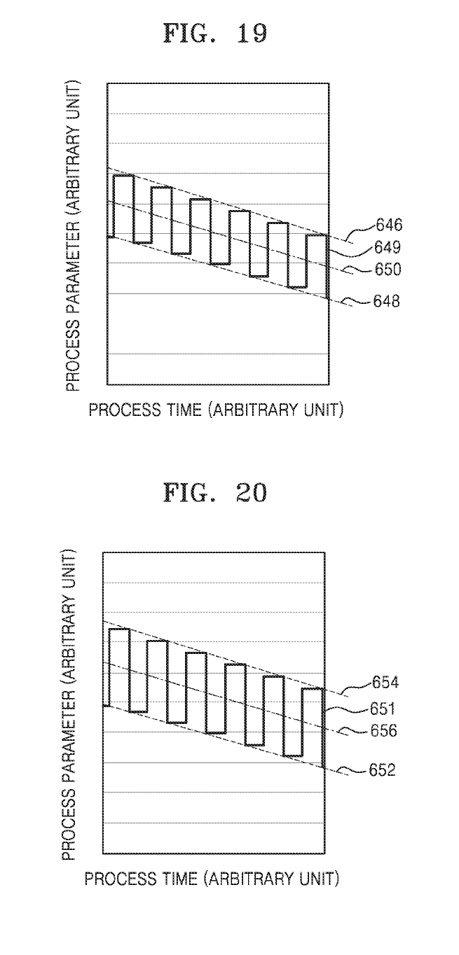

FIGS. 18, 19 and 20 illustrate diagrams explanatory of methods of controlling a process parameter by the controller 300 of the plasma processing apparatus 1000 of FIG. 1, according to an embodiment of the inventive concepts.

In detail, the control methods depicted in FIGS. 18 through 20 may be the same as the control method depicted in FIG. 14 except that frequency, the number of pulses, pulse width, or amplitude of a cycle of a process parameter is controlled by using different cyclic ramping conditions 643, 649, and 651. In describing FIGS. 18 through 20, contents that are identical to that of FIG. 14 may be briefly described or omitted. The controller 300 of the plasma processing apparatus 1000 may control at least one of process parameters described with respect to FIGS. 12-14 as the cyclic ramping conditions 643, 649, and 651.

Comparing the cyclic ramping condition 643 of FIG. 18 with the cyclic ramping condition 605 of FIG. 14, a period of a cycle of a process parameter in the cyclic ramping condition 643 is larger than in the cyclic ramping condition 605, and the number of pulses in the cyclic ramping condition 643 is smaller than those of the cyclic ramping condition 605 of FIG. 14. The cyclic ramping condition 643 of FIG. 18 may be characterized as a continuous decrease in a maximum value 640 and a minimum value 642 of the cycle of the process parameter. The cyclic ramping condition 643 of FIG. 18 may denote a continuous decrease in an intermediate value 644 of the cycle of the process parameter.

Comparing the cyclic ramping condition 649 of FIG. 19 with the cyclic ramping condition 605 of FIG. 14, a pulse width of a cycle of a process parameter in the cyclic ramping condition 649 is larger than in the cyclic ramping condition 605 of FIG. 14. The cyclic ramping condition 649 of FIG. 19 may be characterized as a continuous decrease in a maximum value 646 and a minimum value 648 of the cycle of the process parameter. The cyclic ramping condition 649 of FIG. 19 may denote a continuous decrease in an intermediate value 650 of the cycle of the process parameter.

Comparing the cyclic ramping condition 651 of FIG. 19 with the cyclic ramping condition 605 of FIG. 14, an amplitude of a cycle of a process parameter in the cyclic ramping condition 651 is larger than in the cyclic ramping condition 605 of FIG. 14. The cyclic ramping condition 651 of FIG. 20 may be characterized as a continuous decrease in a maximum value 654 and a minimum value 652 of the cycle of the process parameter. The cyclic ramping condition 651 of FIG. 20 may denote a continuous decrease in an intermediate value 656 of the cycle of the process parameter.

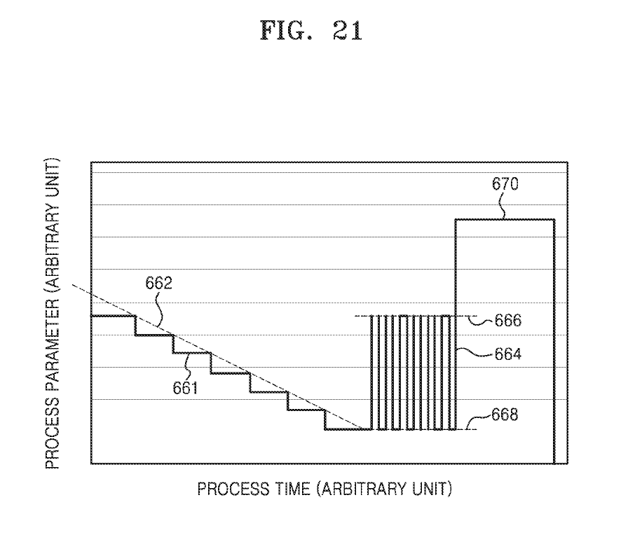

FIG. 21 illustrates a diagram explanatory of a method of processing a process parameter by a controller of the plasma processing apparatus of FIG. 1, according to an embodiment of the inventive concepts.

In detail, when the control method of FIG. 21 is compared with the control methods of FIGS. 12 through 14, the control methods of FIG. 21 and FIGS. 12 through 14 are the same except that, in the control method of FIG. 21, a process parameter is controlled as ramping condition 661 and cyclic condition 664 in which the ramping condition 661 and the cyclic condition 664 are separated (i.e., the ramping condition 661 and the cyclic condition 664 occur in sequence), and the process parameter is also controlled as a stable condition 670. In describing FIG. 21, contents that are identical to that of FIGS. 12 through 14 may be briefly described or omitted.

The controller 300 of the plasma processing apparatus 1000 (refer to FIG. 1) may control at least one of process parameters as described with respect to FIGS. 12-14 as a ramping condition 661. The ramping condition 661 may denote the injection of a process parameter (e.g., a process gas) continuously reduced in the process chamber 1110 along with a process time. FIG. 21 shows a case that a maximum value 662 of the process parameter as a ramping condition 661 is continuously decreased.

After controlling the process parameter under a ramping condition, the controller 300 of the plasma processing apparatus 1000 (refer to FIG. 1) may control at least one of process parameters under the cyclic condition 664. The cyclic condition 664 may denote a cyclical change of a process parameter (e.g., a process gas) along with a process time. FIG. 21 shows a case that a maximum value 666 and a minimum value 668 of a cycle of a process parameter as the cyclic condition 664 are sequentially changed.

After controlling the process parameter as a cyclic condition, the controller 300 of the plasma processing apparatus 1000 (refer to FIG. 1) may control at least one of process parameters as the stable condition 670. The stable condition 670 may denote a controlling of a process parameter (e.g., a process gas) to be a constant value as a process time lapses.

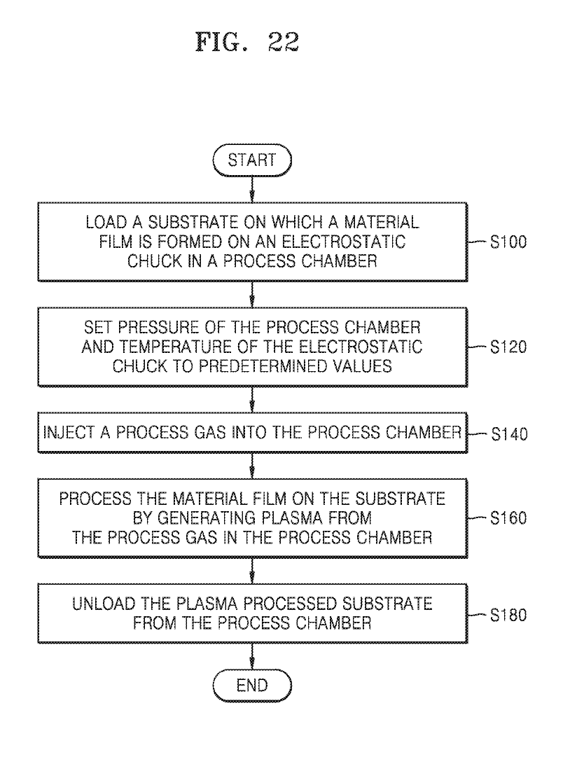

FIG. 22 illustrates a flowchart of a method of processing plasma by the plasma processing apparatus 1000 of FIG. 1, according to an embodiment of the inventive concepts.

In detail, in the description as provided with respect to FIG. 22, like reference numerals indicate elements that are identical to the elements of FIG. 1. In describing FIG. 22, contents that are identical to those of FIG. 1 may be briefly described or omitted.

The method of processing plasma in the flowchart of FIG. 22 may include an operation of mounting (loading) a substrate 90 on an electrostatic chuck 101 of a process chamber 1110 (S100). The substrate 90 loaded into the process chamber 1110 may have a material film such as for example an oxide film or a nitride film previously formed thereon.

A pressure of the process chamber 1110 and a temperature of the electrostatic chuck 101 are set to predetermined values (S120). The pressure of the process chamber 1110 and the temperature of the electrostatic chuck 101 may be elements of process parameters. The pressure of the process chamber 1110 and the temperature of the electrostatic chuck 101 may be changed in a process of treating plasma.

Next, a process gas is injected into the process chamber 1110 (S140). As described above, the process gas may be a part of the process parameter and may be injected into the process chamber 1110 through an upper-gas injection unit 500 or a side-gas injection unit 400. For example, the process gas may be injected into the process chamber 1110 by the side-gas injection unit 400. The process gas may be obliquely injected into the process chamber 1110 from a sidewall of the process chamber 1110 by the side-gas injection unit 400.

Next, the material film on the substrate 90 is plasma processed by generating plasma from the process gas injected into the process chamber 1110 (S160). The process gas injected into the process chamber 1110, as described above, may be turned into plasma by using the plasma generation units 250 and 260. The plasma processing may be an etch process of the material film on the substrate 90.

The plasma generation units 250 and 260 may include a high frequency power source 1157, an impedance matcher 1158, a high frequency antenna 1154, and a bias power source 220 as described with respect to FIG. 1. A power value (power) by the high frequency power source 1157 and the bias power source 220 may constitute a process parameter.

In the plasma processing, a process parameter of a series of processes may be controlled by the controller 300. The controller 300 may control under a cyclic ramping condition at least one of a pressure of the process chamber 1110, a temperature of the electrostatic chuck 101, a flow rate of a process gas supplied from the side-gas injection unit 400 and the upper-gas injection unit 500, and power of the plasma generation units 250 and 260. Next, the plasma processing is completed by unloading the plasma processed substrate 90 from the process chamber 1110 (S180).

While the inventive concepts have been particularly shown and described with reference to preferred embodiments thereof, it will be understood by those of ordinary skill in the art that various changes, substitutions in form and details may be made therein without departing from the spirit and scope of the inventive concepts as defined by the appended claims. The example embodiments described above should be considered in descriptive sense only and not for purposes of limitation. Therefore, the scope of the inventive concepts is defined not by the detailed descriptions but by the appended claims.

What is claimed is:

1. A plasma processing apparatus comprising:
a process chamber having an inner space;
an electrostatic chuck configured to electrostatically hold a substrate in the process chamber;
a side-gas injection unit above the electrostatic chuck and including at least one gas nozzle including an inclined gas flow path inclined with respect to a nozzle axis to obliquely inject a process gas into the process chamber from a sidewall of the process chamber;
a plasma generation unit configured to generate plasma from the process gas injected into the process chamber; and
a controller configured to control the electrostatic chuck, the side-gas injection unit, and the plasma generation unit.

2. The plasma processing apparatus of claim 1, wherein the nozzle axis is in a perpendicular direction to the sidewall of the process chamber, and the at least one gas nozzle includes another inclined gas flow path, and
wherein the at least one gas nozzle is configured to inject the process gas through the inclined gas flow path at a first inclination angle in a clockwise direction with respect to the nozzle axis and through the another inclined gas flow path at a second inclination angle in a counter clockwise direction with respect to the nozzle axis.

3. The plasma processing apparatus of claim 2, wherein the first inclination angle and the second inclination angle are the same.

4. The plasma processing apparatus of claim 1, wherein the process chamber has a cylindrical shape, and the at least one gas nozzle comprises a plurality of gas nozzles greater than one separated from each other along a circumferential direction of the process chamber.

5. The plasma processing apparatus of claim 1, wherein the at least one gas nozzle comprises a rotatable gas nozzle configured to rotate with respect to the nozzle axis.

6. The plasma processing apparatus of claim 1, wherein the side-gas injection unit comprises a gas inlet through which the process gas is provided, and a plurality of branch gas flow paths connected to the gas inlet to distribute the process gas, and
wherein the inclined gas flow path of the at least one gas nozzle is connected to the plurality of branch gas flow paths.

7. The plasma processing apparatus of claim 6, wherein the plurality of branch gas flow paths comprise a buffer gas flow path connected to a branch point at which the process gas is branched to the plurality of branch gas flow paths.

8. The plasma processing apparatus of claim 1, further comprising an upper-gas injection unit configured to inject a second process gas toward the substrate from above the process chamber.

9. The plasma processing apparatus of claim 8, wherein the process gas and the second process gas are different gases.

10. A plasma processing apparatus comprising:
a process chamber having an inner space;
an electrostatic chuck configured to electrostatically hold a substrate in the process chamber;
a side-gas injection unit above the electrostatic chuck and configured to inject a process gas into the process chamber from a sidewall of the process chamber;
an upper-gas injection unit configured to inject the process gas in a direction toward the substrate from above the process chamber;
a plasma generation unit configured to generate plasma from the process gas injected into the process chamber; and
a controller configured to control, under a cyclic ramping condition, at least one process parameter including a pressure of the process chamber, a temperature of the electrostatic chuck, a flow rate of the process gas injected from the side-gas injection unit and the upper-gas injection unit, and power of the plasma generation unit.

11. The plasma processing apparatus of claim 10, wherein the controller is configured to control the at least one process parameter under the cyclic ramping condition in which a cycle of the at least one process parameter is continuously increased or decreased as a process time lapses, wherein the cyclic ramping condition is a combination of a ramping condition in which the process parameter is continuously increased or decreased as the process time lapses and a cyclic condition in which the process parameter is cyclically changed as the process time lapses.

12. The plasma processing apparatus of claim 11, wherein the controller is configured to control the process parameter under the cyclic ramping condition in which an intermediate value of the cycle of the process parameter is continuously increased or decreased as the process time lapses.

13. The plasma processing apparatus of claim 11, wherein the controller is configured to control at least one of a period, a number of pulses, and a pulse width of the cycle of the process parameter of the cyclic condition.

14. The plasma processing apparatus of claim 11, wherein the controller is configured to sequentially control the cyclic ramping condition to separate the ramping condition and the cyclic condition.

15. The plasma processing apparatus of claim 14, wherein the controller is configured to control the process parameter under a stable condition by maintaining the process parameter at a constant value.

16. A plasma processing apparatus comprising:
a process chamber having an inner space;
an electrostatic chuck configured to electrostatically hold a substrate in the process chamber;
a side-gas injection unit above the electrostatic chuck and configured to obliquely inject a process gas into the process chamber from a sidewall of the process chamber through at least one gas nozzle having an inclined gas flow path that is inclined with respect to a nozzle axis;
an upper-gas injection unit configured to inject the process gas in a direction toward the substrate from above the process chamber;
a plasma generation unit configured to generate plasma from the process gas injected into the process chamber; and
a controller configured to control, under a cyclic ramping condition, at least one process parameter including a pressure of the process chamber, a temperature of the electrostatic chuck, a flow rate of the process gas injected from the side-gas injection unit and the upper-gas injection unit, and power of the plasma generation unit.

17. The plasma processing apparatus of claim 16, wherein the nozzle axis is in a perpendicular direction to the sidewall of the process chamber, and the at least one gas nozzle includes another inclined gas flow path, and
wherein the at least one gas nozzle is configured to obliquely inject the process gas through the inclined gas flow path at a first inclination angle in a clockwise direction with respect to the nozzle axis and through the another inclined gas flow path at a second inclination angle in a counter clockwise direction with respect to the nozzle axis.

18. The plasma processing apparatus of claim 16, wherein the side-gas injection unit comprises a gas inlet through which the process gas is provided, and a plurality of branch gas flow paths connected to the gas inlet to distribute the process gas, and
wherein the inclined gas flow path of the at least one gas nozzle is connected to the plurality of branch gas flow paths, and the plurality of branch gas flow paths comprise a buffer gas flow path connected to a branch point at which the process gas is branched to the plurality of branch gas flow paths.

19. The plasma processing apparatus of claim 16, wherein the controller is configured to control the at least one process parameter under the cyclic ramping condition in which a cycle of the process parameter is continuously increased or decreased as a process time lapses, wherein the cyclic ramping condition is a combination of a ramping condition in which the process parameter is continuously increased or decreased as the process time lapses and a cyclic condition in which a maximum value and a minimum value of the process parameter are cyclically and sequentially changed as the process time lapses.

20. The plasma processing apparatus of claim 19, wherein the controller is configured to control the process parameter under the cyclic ramping condition in which an intermediate value of the cycle of the process parameter is continuously increased or decreased, and
the controller is configured to control at least one of a period, a number of pulses, and a pulse width of the cycle of the process parameter under the ramping condition and the cyclic condition.
